(19) United States
(12) Patent Application Publication
(10) Pub. No.: US 2010/0179778 A1
(43) Pub. Date: Jul. 15, 2010

(54) Embedded monitoring system for batteries

(76) Inventors: Lonnie Calvin Goff, Tempe, AZ (US); Mark Edmond Eidson, Tempe, AZ (US); Mark Ronald Schade, Chandler, AZ (US); Michael Richard Conley, Thousand Oaks, CA (US)

Correspondence Address: Lonnie Goff, 1433 S. Mill Ave, Tempe, AZ, 85281, US

(21) Appl. No.: 12/321,310

(22) Filed: Jan. 15, 2009

(51) Int. Cl. H01M 10/48; G01R 19/00

(52) U.S. Cl. 702/64; 429/90

(57) ABSTRACT

A computer system embedded inside a battery which monitors the state of the battery and transfers this information to an external device.

### CROSS REFERENCE TO RELATED APPLICATIONS

This application is related to application Ser. No. 12/075,212 filed by the present inventors on Mar. 10, 2008 and entitled “Battery Monitor System Attached to a Vehicle Wiring Harness”. This application also relates to application Ser. No. 12/070,793 filed by the present inventors on Feb. 20, 2008 and entitled “Multi-function Battery Monitor System for Vehicles”. This application also relates to a recent application filed by the present inventors on Jan. 8, 2009 and entitled “Battery Monitoring Algorithms for Vehicles”.

### FEDERALLY SPONSORED RESEARCH OR DEVELOPMENT

Not Applicable

### SEQUENCE LISTING, TABLE OR COMPUTER PROGRAM LISTING ON CD

Not Applicable

### BACKGROUND OF THE INVENTION

1. Field of Invention

The present invention relates to the field of computers. In particular it relates to computer based methods for measuring and making available important internal operating conditions in both vehicular and standby power batteries.

2. Prior Art

All batteries fail. The operational state of a vehicle's battery is therefore important to know. In some situations this information could be life-saving such as when operating in combat zones or under severe weather conditions.

The operational state of a battery can be approximated by various methods that include measuring the voltage of the battery, calculating the charge state of the battery, measuring the battery under load, measuring the battery's specific gravity and measuring the battery's internal impedance. The results rendered by all of these methods require knowledge of the internal temperature of the battery. Unfortunately the internal temperature of the battery is not available except in those special cases where the vehicle is not being driven and the vehicle's battery includes filler caps whereby a temperature probe or an infrared temperature sensor can be used to measure the temperature of the battery's electrolyte.

A vehicle's charging system also needs to know the temperature of the battery when the engine is running in order to prevent battery overcharging with its subsequent loss of electrolyte. Some of today's automobile manufacturers, for example Volvo, provide a temperature sensor attached externally to the battery's case. The temperature of the case, however, does not necessarily equate well with the temperature inside the battery. Measurements made under different driving conditions by the present inventors have shown that the temperature at different locations taken at the same time can vary as much as 41 degrees Fahrenheit depending upon where on the case these measurements are made.

Also problematic with today's battery technology is the lack of a means to measure the voltage of individual cells. Knowledge of the voltage level of individual cells is indicative of the overall health of the battery. A weak cell cannot be “seen” by measuring a battery's voltage at its terminal posts.

Finally, specific gravity tests are recognized as being one the best methods for determining the condition of liquid acid batteries. Unfortunately most vehicular batteries sold today are sealed. They have no filler caps so therefore offer no access to the battery acid. It is not possible to perform specific gravity testing on these batteries.

It is therefore deemed desirable to know the internal temperature of the battery both when the vehicle is being driven and when the vehicle is at rest. It is also deemed desirable to know the specific gravity and the voltage of individual battery cells. Finally it is deemed desirable to dynamically know in real-time mode the temperature, specific gravity and the voltage of all of the battery cells when the vehicle is both being operated and when the vehicle is at rest.

Lastly it would be desirable to dynamically know in real-time mode the temperature, specific gravity and the voltage of all of the battery cells in a bank of standby/backup power batteries.

### BRIEF SUMMARY OF THE INVENTION

The present invention makes use of a computer system that is designed to reside inside the case of a battery. The computer system can either make use of one or more of the battery's cells as its power source or include provisions for a separate power source. The computer system includes one or more temperature sensors, one or more specific gravity sensors, a means for measuring time, a means for measuring voltage and a data storage facility for retaining a history of measurements. The computer system also includes an electrical interface that can transfer information to locations external to the battery.

Per one embodiment, the computer system includes a temperature sensor, a specific gravity sensor and a voltage sensor. Information read from these sensors is transferred over the battery's power cable by using an automotive industry standard protocol such as the LIN-Bus (Local Interconnect Network).

Per another embodiment, the computer system includes specific gravity sensors installed in each battery cell and a voltage sensor. Information read from these sensors is transferred over a wired bus using an automotive industry standard protocol such as the CAN-Bus (Controller Area Network).

Per yet another embodiment, the computer system includes temperature sensors installed in each battery cell and a voltage sensor. Information read from these sensors is transferred using a wireless based protocol such as IEEE 802.15.4.

### BRIEF DESCRIPTION OF THE DRAWINGS

FIG. 1 is a block diagram of a computer based system shown embedded inside an automotive battery. This system has capabilities for measuring voltage, temperature and specific gravity. It also has capabilities for transmitting and receiving data across the power cable that is attached to the battery terminal.

FIG. 1A is a flow chart illustrating the steps taken by the computer system of FIG. 1 to make available internal battery temperature, voltage and specific gravity information to an external location.

FIG. 2 is a block diagram of a computer based system shown embedded inside an automotive battery. This system has capabilities for measuring the voltage and the specific gravity of each individual battery cell. It also has capabilities for transmitting and receiving data across a communication channel.

FIG. 2A is a flow chart illustrating the steps taken by the computer system of FIG. 2 to make available to a location outside of the battery the voltage and the specific gravity of each battery cell.

FIG. 3 is a block diagram of a computer based system shown embedded inside an automotive battery. This system has capabilities for measuring the voltage and the temperature of each individual battery cell. It also has capabilities for transmitting and receiving data across a wireless communication medium.

FIG. 3A is a flow chart illustrating the steps taken by the computer system of FIG. 3 to make available to a location outside of the battery the voltage and the temperature readings of each cell of the battery.

### DETAILED DESCRIPTION OF THE INVENTION

The following descriptions are provided to enable any person skilled in the art to make and use the invention and is provided in the context of three particular embodiments. Various modifications to these embodiments are possible and the generic principles defined herein may be applied to this and other embodiments without departing from the spirit and scope of the invention. Thus the invention is not intended to be limited to the embodiments shown but is to be accorded the widest scope consistent with the principles, features and teachings disclosed herein.

In accordance with one embodiment, the present invention makes use of a computer system that resides inside a battery's case and communicates to the outside world through the power cable attached to the battery's power terminal. The computer system also includes temperature, voltage and specific gravity sensors. The computer system's central processing unit also has the ability to measure time and includes facilities for storing data.

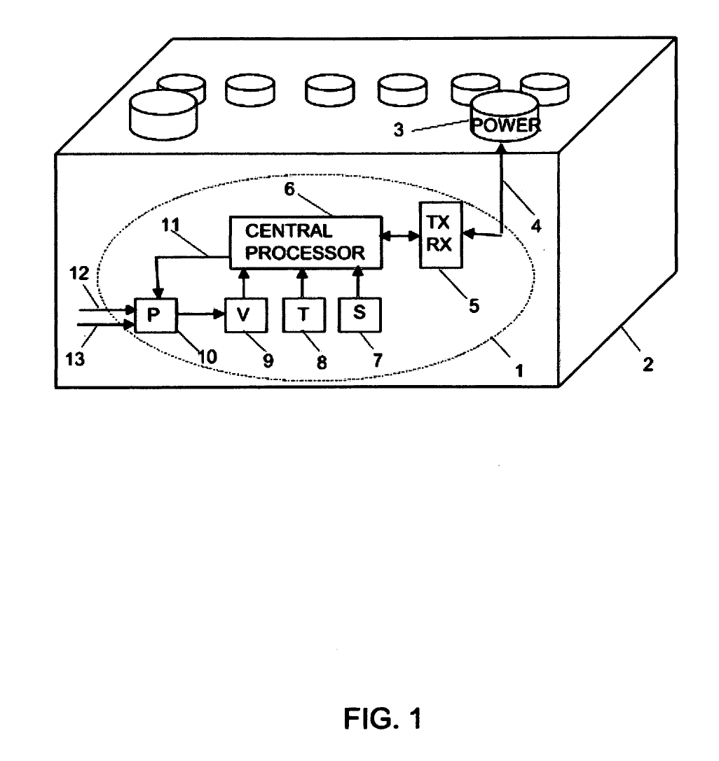

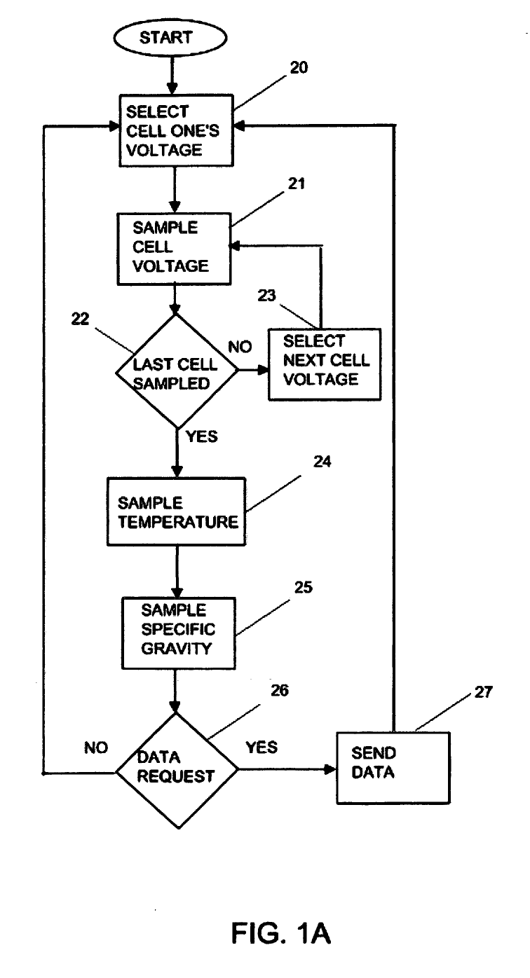

FIG. 1 is a block diagram illustrating computer system 1 shown embedded inside battery 2. Computer system 1 includes an electrical connection to battery terminal 3 through conductor 4. Transceiver 5 is used to receive and transmit data between central processor 6 and one or more external devices (not shown) attached to the terminal 3 power cable. Specific gravity sensor 7 measures the specific gravity of a battery cell. This information is retrieved and saved by central processor 6. Temperature sensor 8 measures the ambient temperature inside the battery's case. This information is retrieved and saved by central processor 6. Central processor 6 uses control bus 11 to cause power multiplexer 10 to select a cell voltage to be gated to voltage sensor 9. Cell one's voltage is inputted to power multiplexer 10 on wire 12. Cell two's voltage is inputted on wire 13. Voltages from the other cells (not shown) are also inputted to power multiplexer 10. The voltage measured by voltage sensor 9 is retrieved and saved by central processor 6. Central processor 6 uses transceiver 5 to monitor data activity which may be present on power terminal 3.

FIG. 1A is a flowchart illustrating those steps taken by computer system 1 in FIG. 1 in order to gather information about the internal state of the battery and to make this information available to an external device (not shown). In step 20 cell number one's input voltage 12 in FIG. 1 is selected by central processor 6 via bus 11 so that this cell voltage is gated through multiplexer 10 in FIG. 1 and made available to voltage sensor 9 of FIG. 1. The cell voltage is sampled at step 21 by central processor 6 of FIG. 1 and saved. In step 22 if all of the battery cell voltages have been sampled program control proceeds to step 24. If the last cell has not yet been sampled program control goes to step 23 where the next cell's voltage is selected by central processor 6 using bus 11 of FIG. 1. Steps 21, 22 and 23 repeat until the voltage for all of the battery's cells have been read and saved. At step 24 temperature sensor 8 in FIG. 1 is sampled by central processor 6 in FIG. 1 and saved. At step 25 specific gravity sensor 7 in FIG. 1 is sampled and saved by central processor 6 in FIG. 1. At step 26 a protocol check is made using transceiver 5 in FIG. 1 by central processor 6 in FIG. 1 to see if an external device (not shown) is requesting data. If no request is pending, program control returns to step 20. If data is requested, program control proceeds to step 27 where the requested data is transferred using transceiver circuit 5 in FIG. 1 by central processor 6 in FIG. 1. The data is sent to terminal 3 in FIG. 1 using conductor 4 in FIG. 1. Data then travels across the power cable (not shown) which is attached to connector 3 in FIG. 1 to the requesting device (not shown). Program control then returns to step 20. The flowchart repeats.

In accordance with another embodiment, the present invention makes use of a computer system that resides inside a battery's case and communicates to the outside world through a communication connector installed in the battery's case. The computer system also includes a voltage sensor and a sufficient number of specific gravity sensors to monitor all the battery's cells. The computer system's central processing unit also has the ability to measure time and includes facilities for storing data.

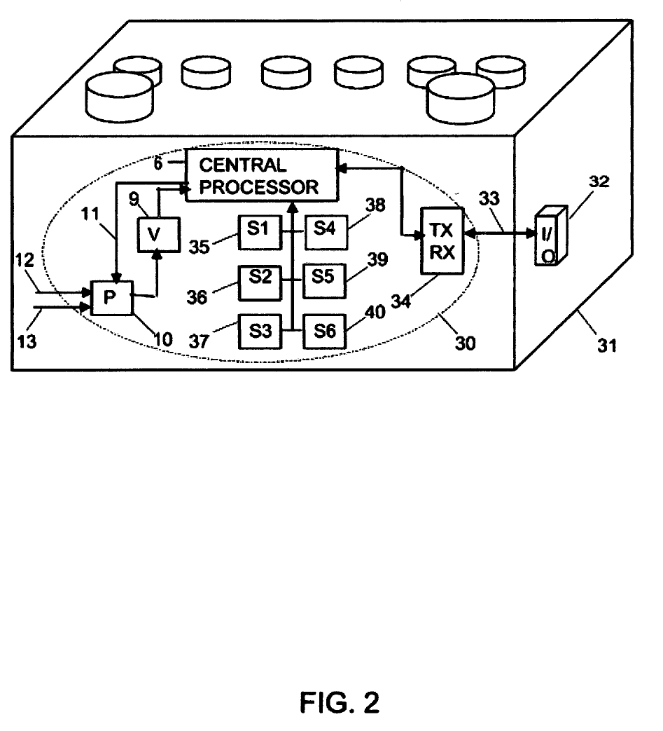

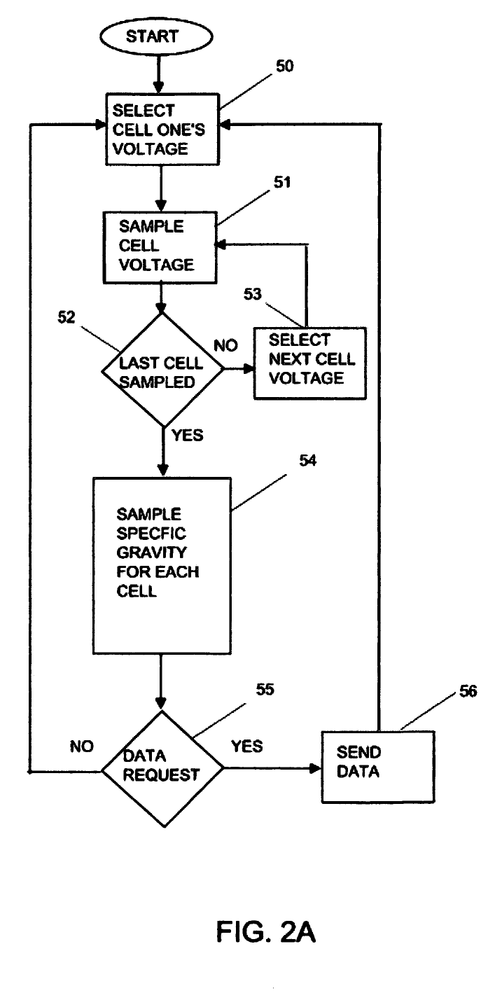

FIG. 2 is a block diagram illustrating computer system 30 shown embedded inside battery 31. Computer system 30 includes a data path to input/output communication connector 32 through conductor 33. Transceiver 34 is used to receive and transmit data between central processor 6 and one or more external devices (not shown) attached to connector 32. Specific gravity sensors 35-40 measure the specific gravity of the battery cells. This information is retrieved and saved by central processor 6. Central processor 6 uses control bus 11 to cause power multiplexer 10 to select a cell voltage to be gated to voltage sensor 9. Cell one's voltage is inputted to power multiplexer 10 on wire 12. Cell two's voltage is inputted on wire 13. Voltages from the other cells (not shown) are also inputted to power multiplexer 10. The voltage measured by voltage sensor 9 is retrieved and saved by central processor 6. Central processor 6 uses transceiver 34 to monitor data activity which may be present on connector 32.

FIG. 2A is a flowchart illustrating those steps taken by computer system 30 in FIG. 2 in order to gather information about the internal state of the battery and to make this information available to an external device (not shown). In step 50 cell number one's input voltage 12 in FIG. 2 is selected by central processor 6 via bus 11 in FIG. 2 so that this cell voltage is gated through multiplexer 10 in FIG. 2 and made available to voltage sensor 9 of FIG. 2. The cell voltage is sampled at step 51 and saved by central processor 6 in FIG. 2. In step 52 if all of the battery cell voltages have been sampled program control proceeds to step 54. If the last cell has not yet been sampled program control goes to step 53 where the next cell's voltage is selected by central processor 6 using bus 11 of FIG. 2. Steps 51, 52 and 53 repeat until the voltage for all of the battery's cells have been read and saved. At step 54 all of the specific gravity sensors 35, 36, 37, 38, 39, 40 in FIG. 2 are sampled and saved by central processor 6 in FIG. 2. At step 55 a protocol check is made using transceiver 34 in FIG. 2 by central processor 6 in FIG. 2 to see if an external device (not shown) is requesting data. If no request is pending, program control returns to step 50. If data is requested, program control proceeds to step 56 where the requested data is transferred using transceiver circuit 34 in FIG. 2 by central processor 6 in FIG. 2. The data is sent to connector 32 in FIG. 2 using conductor 33 in FIG. 2. Data then travels across the media attached to input/output connector 32 to the requesting device (not shown). Program control then returns to step 50. The flowchart repeats.

In accordance with yet another embodiment, the present invention makes use of a computer system that resides inside a battery's case and communicates to the outside world through an antenna installed in the battery's case. The computer system includes a voltage sensor and a sufficient number of temperature sensors to monitor all the battery's cells. The computer system's central processing unit also has the ability to measure time and includes facilities for storing data.

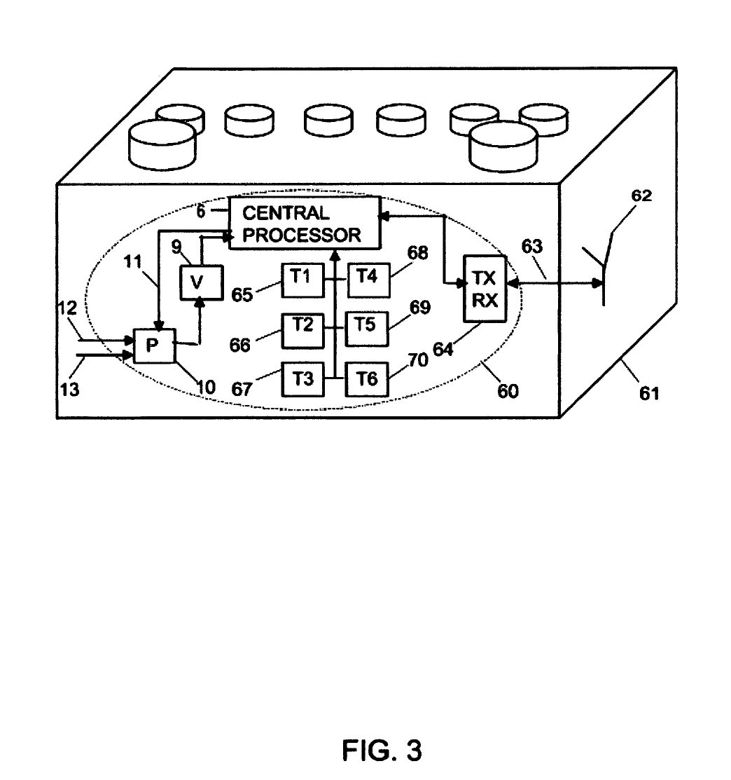

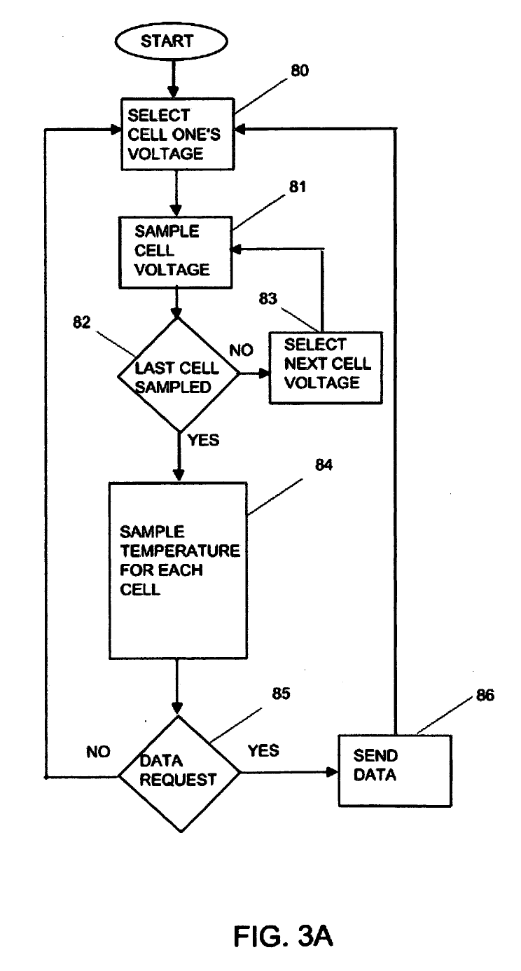

FIG. 3 is a block diagram illustrating computer system 60 shown embedded inside battery 61. Computer system 60 includes a data path to antenna 62 through conductor 63. Transceiver 64 is used to receive and transmit data between central processor 6 and one or more external devices (not shown). Temperature sensors 65-70 measure the temperature of the battery cells. This information is retrieved and saved by central processor 6. Central processor 6 uses control bus 11 to cause power multiplexer 10 to select a cell voltage to be gated to voltage sensor 9. Cell one's voltage is inputted to power multiplexer 10 on wire 12. Cell two's voltage is inputted on wire 13. Voltages from the other cells (not shown) are also inputted to power multiplexer 10. The voltage measured by voltage sensor 9 is retrieved and saved by central processor 6. Central processor 6 uses transceiver 64 to monitor data activity which may be present on antenna 62.

FIG. 3A is a flowchart illustrating those steps taken by computer system 60 in FIG. 3 in order to gather information about the internal state of the battery and to make this information available to an external device (not shown). In step 80 cell number one's input voltage 12 in FIG. 3 is selected by central processor 6 via bus 11 in FIG. 3 so that this cell voltage is gated through multiplexer 10 in FIG. 3 and made available to voltage sensor 9 of FIG. 3. The cell voltage is sampled at step 81 and saved by central processor 6 in FIG. 3. In step 82 if all of the battery cell voltages have been sampled program control proceeds to step 84. If the last cell has not yet been sampled program control goes to step 83 where the next cell's voltage is selected by central processor 6 using bus 11 of FIG. 3. Steps 81, 82 and 83 repeat until the voltage for all of the battery's cells have been read and saved. At step 84 all of the temperature sensors 65, 66, 67, 68, 69, 70 in FIG. 3 are sampled and saved by central processor 6 in FIG. 3. At step 85 a protocol check is made using transceiver 64 in FIG. 3 by central processor 6 in FIG. 3 to see if an external device (not shown) is requesting data. If no request is pending, program control returns to step 80. If data is requested, program control proceeds to step 86 where the requested data is transferred using transceiver circuit 64 in FIG. 3 by central processor 6 in FIG. 3. The data is sent to antenna 63 in FIG. 3 using conductor 63 in FIG. 3. Data then travels across the wireless media to the requesting device (not shown). Program control then returns to step 80. The flowchart repeats.

### ADVANTAGE

Specific gravity tests are recognized as being one the best methods for determining the condition of liquid acid batteries. Unfortunately most vehicular batteries sold today are sealed. They have no filler caps so therefore offer no access to the battery acid. It is not possible to perform specific gravity testing on these batteries.

Knowledge of a battery's temperature is essential when performing battery load testing, when calculating the battery's state of charge or when charging the battery either by driving the vehicle or by using a standalone battery charger. The measurement of the ambient temperature near the battery is typically the best solution offered by today's technology. Except in the special situation where the vehicle is at rest and its battery has filler caps, the temperature inside the battery cannot be measured.

The voltage of individual cells inside a battery is also an important indicator of the battery's health. The battery case, however, prevents access to the individual cells. A weak cell cannot be “seen” by measuring a battery's voltage at its terminal posts.

The distinct advantage of this invention is that the voltage, temperature and specific gravity of each individual cell can be made available under any and all operating conditions at any point in time. Various embodiments of this invention require little or no modification to the battery's case.

The present inventors are cognizant of the harsh environment inside batteries. Typically these batteries contain liquid sulfuric acid which can readily destroy electrical circuits. It is understood that the embedded computer system of this invention must be encased in a material that is impervious to battery acid. Polymers such as polypropylene or polyethylene are examples of viable solutions.

What is claimed is:

1. A computer system device embedded inside a battery that includes the means for measuring some combination of voltage, temperature and specific gravity and includes the means to transfer this information outside the battery.

2. The computer system device of claim 1 wherein said means to transfer information outside the battery makes use of the battery's power cable and makes use of the vehicle standard local interconnect network protocol.

3. The computer system device of claim 1 wherein said means to transfer information outside the battery makes use of an input/output communication connector installed in the battery's case and makes use of the vehicle standard controller area network protocol.

4. The computer system device of claim 1 wherein said means to transfer information outside the battery makes use of an antenna installed in the battery's case and makes use of an industry standard wireless protocol.
